(19) United States
(12) Patent Application Publication
(10) Pub. No.: US 2024/0292594 A1
(43) Pub. Date: Aug. 29, 2024

(54) SEMICONDUCTOR MEMORY DEVICE AND METHOD OF FABRICATING THE SAME

(71) Applicant: SAMSUNG ELECTRONICS CO., LTD., Suwon-si (KR)

(72) Inventors: SangHyun LEE, Suwon-si (KR); Kiseok LEE, Suwon-si (KR); Seokhan PARK, Suwon-si (KR); Sung-Min PARK, Suwon-si (KR); Iljae SHIN, Suwon-si (KR); Dongjun LEE, Suwon-si (KR); Jinwoo HAN, Suwon-si (KR)

(21) Appl. No.: 18/384,407

(22) Filed: Oct. 27, 2023

(30) Foreign Application Priority Data
Feb. 27, 2023 (KR) 10-2023-0026050

(51) Int. Cl. H10B 12/00

(52) U.S. Cl. CPC H10B 12/30; H10B 12/05; H10B 12/50

(57) ABSTRACT

A semiconductor memory device includes a semiconductor substrate; a stack structure that includes word lines and interlayer dielectric patterns that are alternately stacked on the semiconductor substrate; an etch stop layer on the stack structure; semiconductor patterns that penetrate the word lines; a bit line in contact with the semiconductor patterns; capping dielectric patterns between the bit line and the word lines, the capping dielectric patterns covering sidewalls of the word lines; and a data storage element on the semiconductor substrate, wherein a level of a bottom surface of the etch stop layer is the same as a level of a top surface of the data storage element.

### CROSS-REFERENCE TO RELATED APPLICATION

This U.S. nonprovisional application claims priority under 35 U.S.C. § 119 to Korean Patent Application No. 10-2023-0026050 filed on Feb. 27, 2023, in the Korean Intellectual Property Office, the disclosure of which is hereby incorporated by reference in its entirety.

### BACKGROUND

### 1. Field

Embodiments relate to a semiconductor memory device and a method of fabricating the same.

### 2. Description of the Related Art

Semiconductor devices have been highly integrated to meet high performance and low manufacturing cost for customers. Because integration of the semiconductor devices may be an important factor in determining product price, high integration may be increasingly requested. Integration of two-dimensional or planar semiconductor devices may be primarily determined by the area occupied by a unit memory cell, such that it may be greatly influenced by the level of technology for forming fine patterns. The extremely expensive processing equipment needed to increase pattern fineness may set a practical limitation on increasing the integration of the two-dimensional or planar semiconductor devices. There have been proposed three-dimensional semiconductor memory devices having three-dimensionally arranged memory cells.

### SUMMARY

The embodiments may be realized by providing a semiconductor memory device including a semiconductor substrate; a stack structure that includes word lines and interlayer dielectric patterns that are alternately stacked on the semiconductor substrate; an etch stop layer on the stack structure; semiconductor patterns that penetrate the word lines; a bit line in contact with the semiconductor patterns; capping dielectric patterns between the bit line and the word lines, the capping dielectric patterns covering sidewalls of the word lines; and a data storage element on the semiconductor substrate, wherein a level of a bottom surface of the etch stop layer is the same as a level of a top surface of the data storage element.

The embodiments may be realized by providing a semiconductor memory device including a semiconductor substrate; a stack structure that includes word lines and interlayer dielectric patterns that are alternately stacked on the semiconductor substrate; an etch stop layer on the stack structure; semiconductor patterns that penetrate the word lines; a bit line in contact with the semiconductor patterns; capping dielectric patterns between the bit line and the word lines, the capping dielectric patterns covering sidewalls of the word lines; and a data storage element on the semiconductor substrate, wherein a level of a bottom surface of the etch stop layer is the same as a level of a top surface of the bit line.

The embodiments may be realized by providing a semiconductor memory device including a lower substrate; a peripheral layer on the lower substrate; a first stack structure that includes word lines and interlayer dielectric patterns that are alternately stacked on the peripheral layer; a first etch stop layer on the first stack structure; a second stack structure that includes word lines and interlayer dielectric patterns that are alternately stacked on the first etch stop layer; and a second etch stop layer on the second stack structure, wherein the first stack structure and the second stack structure are electrically connected to each other.

### BRIEF DESCRIPTION OF DRAWINGS

Features will be apparent to those of skill in the art by describing in detail exemplary embodiments with reference to the attached drawings in which:

FIG. 1 illustrates a simplified circuit diagram showing a cell array of a semiconductor memory device according to some embodiments.

FIG. 2 illustrates a perspective view partially showing a cell array of a semiconductor memory device according to some embodiments.

FIG. 3 illustrates a plan view showing a semiconductor memory device according to some embodiments.

FIG. 4A illustrates a cross-sectional view taken along line A-A′ of FIG. 3, showing a semiconductor memory device according to some embodiments.

FIG. 4B illustrates a cross-sectional view taken along line B-B′ of FIG. 3, showing a semiconductor memory device according to some embodiments.

FIG. 4C illustrates a cross-sectional view taken along line C-C′ of FIG. 3, showing a semiconductor memory device according to some embodiments.

FIGS. 5, 7, 9, 11, 13, 15, 17, and 19 illustrate plan views showing stages in a method of fabricating a semiconductor memory device according to some embodiments.

FIGS. 6A to 20A illustrate cross-sectional views taken along line A-A′ of FIGS. 5 to 19, showing stages in a method of fabricating a semiconductor memory device according to some embodiments.

FIGS. 6B to 20B illustrate cross-sectional views taken along line B-B′ of FIGS. 5 to 19, showing stages in a method of fabricating a semiconductor memory device according to some embodiments.

FIGS. 6C to 20C illustrate cross-sectional views taken along line C-C′ of FIGS. 5 to 19, showing stages in a method of fabricating a semiconductor memory device according to some embodiments.

FIG. 21 illustrates a cross-sectional view showing a semiconductor memory device according to some embodiments.

FIGS. 22A, 22B, and 22C illustrate cross-sectional views showing a stages in a method of fabricating a semiconductor memory device according to some embodiments.

FIG. 23 illustrates a cross-sectional view showing a semiconductor memory device according to some embodiments.

FIG. 24 illustrates a cross-sectional view showing a semiconductor memory device according to some embodiments.

### DETAILED DESCRIPTION

It will be hereinafter discussed a semiconductor memory device and a method of fabricating the same according to some embodiments in conjunction with the accompanying drawings.

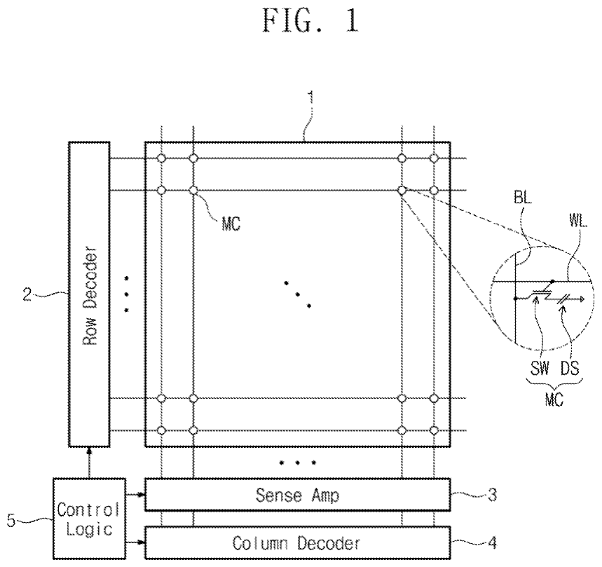

FIG. 1 illustrates a simplified circuit diagram showing a cell array of a semiconductor memory device according to some embodiments.

Referring to FIG. 1, a semiconductor memory device according to an embodiment may include a memory cell array 1, a row decoder 2, a sense amplifier 3, a column decoder 4, and a control logic 5.

The memory cell array 1 may include a plurality of memory cells MC that are arranged three-dimensionally. Each of the memory cells MC may be connected between a word line WL and a bit line BL that cross each other.

Each of the memory cells MC may include a selection element SW and a data storage element DS, and the selection element SW and the data storage element DS may be electrically connected in series to each other. The data storage element DS may be connected between the bit line BL and the selection element SW, and the selection element SW may be connected between the data storage element DS and the word line WL. The selection element SW may be a field effect transistor (FET), and the data storage element DS may be a capacitor or a variable resistor. In an implementation, the selection element SW may include a transistor, a gate electrode of the transistor may be connected to the word line WL, and source/drain terminals of the transistor may be connected to the bit line BL and the data storage element DS.

The row decoder 2 may decode an address that is externally input, and may select one of the word lines WL of the memory cell array 1. The address that is decoded in the row decoder 2 may be provided to a row driver, and in response to a control operation of control circuits, the row driver may provide a certain voltage to a selected word line WL and each of non-selected word lines WL.

In response to an address that is decoded from the column decoder 4, the sense amplifier 3 may detect and amplify a voltage difference between a selected bit line BL and a reference bit line, and may then output the amplified voltage difference.

The column decoder 4 may provide a data delivery path between the sense amplifier 3 and an external device (e.g., a memory controller). The column decoder 4 may decode an address that is externally input and may select one of the bit lines BL.

The control logic 5 may generate control signals that control operations to write data to the memory cell array 1 and/or to read data from the memory cell array 1.

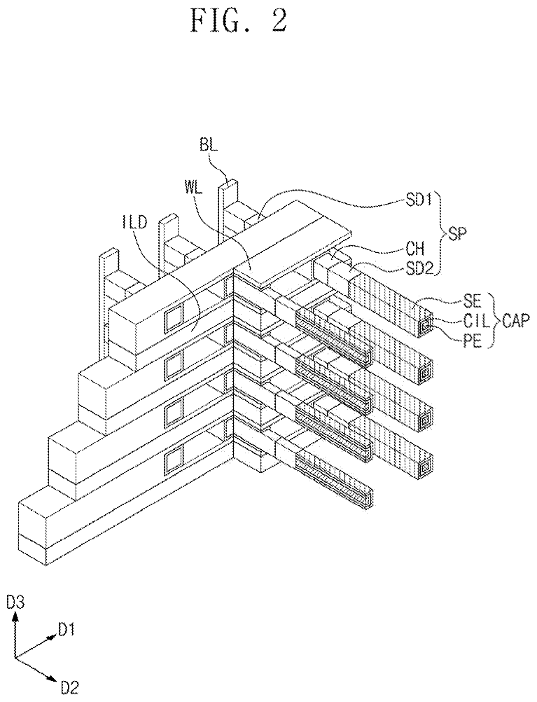

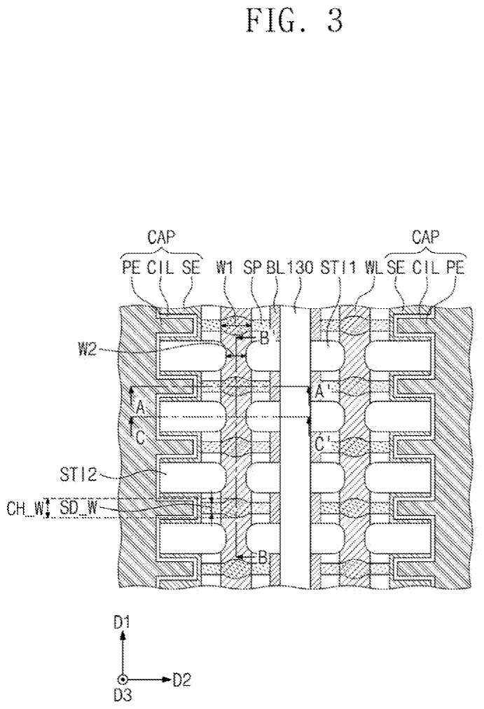

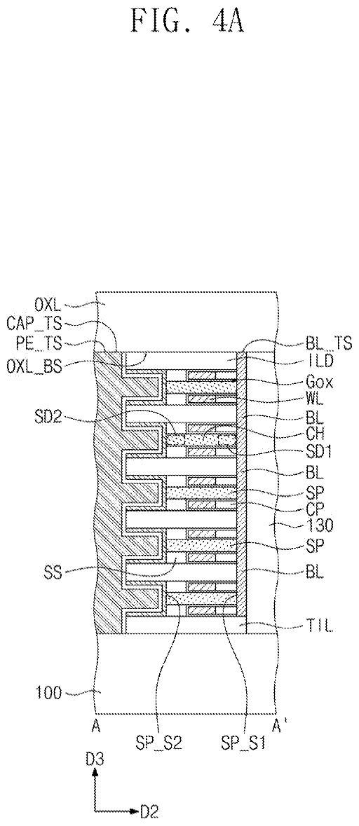

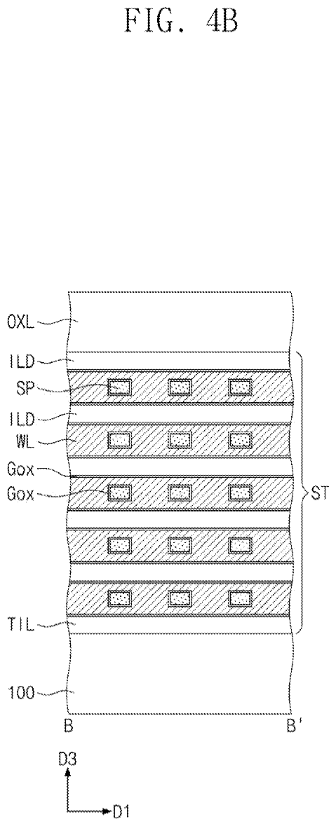

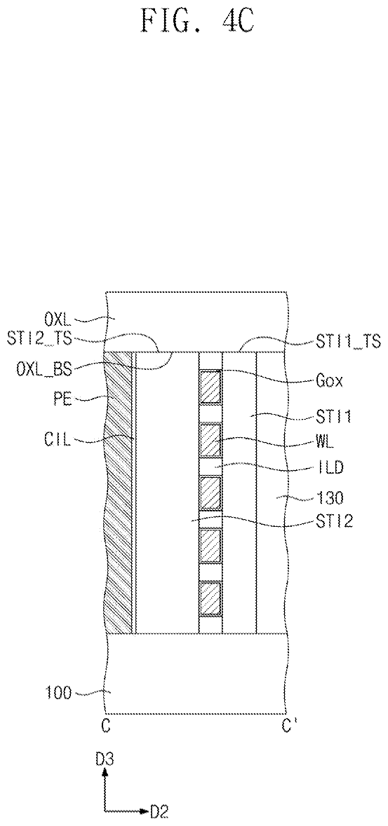

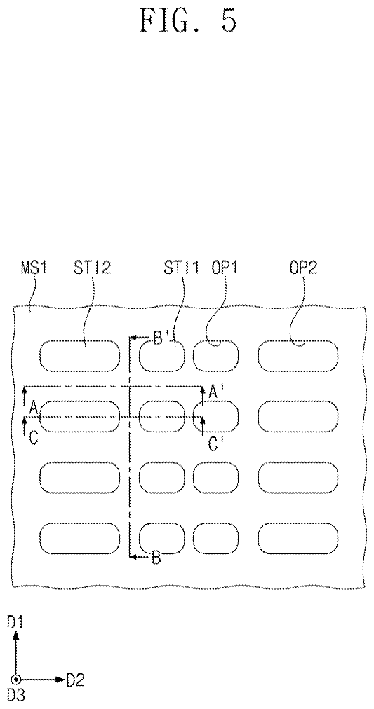

FIG. 2 illustrates a perspective view partially showing a cell array of a semiconductor memory device according to some embodiments. FIG. 3 illustrates a plan view showing a semiconductor memory device according to some embodiments. FIG. 4A illustrates a cross-sectional view taken along line A-A′ of FIG. 3, showing a semiconductor memory device according to some embodiments. FIG. 4B illustrates a cross-sectional view taken along line B-B′ of FIG. 3, showing a semiconductor memory device according to some embodiments. FIG. 4C illustrates a cross-sectional view taken along line C-C′ of FIG. 3, showing a semiconductor memory device according to some embodiments.

Referring to FIGS. 2, 3, 4A, 4B, and 4C, a semiconductor memory device according to an embodiment may include a semiconductor substrate 100, a first separation dielectric pattern STI1 on the semiconductor substrate 100, a second separation dielectric pattern STI2 on the semiconductor substrate 100, a stack structure ST on the semiconductor substrate 100, a data storage element CAP on the semiconductor substrate 100, a bit line BL on the semiconductor substrate 100, a semiconductor pattern SP, a spacer dielectric pattern SS, and a capping dielectric pattern CP between the bit line BL and the data storage element CAP, a vertical dielectric pattern 130 on the semiconductor substrate 100, and an etch stop layer OXL on the stack structure ST.

The semiconductor substrate 100 may have a plate shape that expands or extends along a plane extending in a first direction D1 and a second direction D2. The first direction D1 and the second direction D2 may intersect each other. The first direction D1 and the second direction D2 may be, e.g., horizontal directions that are orthogonal to each other. The semiconductor substrate 100 may have a top surface perpendicular to a third direction D3 that intersects the first direction D1 and the second direction D2. In an implementation, the first, second, and third directions D1, D2, and D3 may be orthogonal to each other. The semiconductor substrate 100 may include, e.g., silicon (Si), germanium (Ge), or silicon-germanium (SiGe), gallium phosphide (GaP), or gallium arsenide (GaAs). In an implementation, the semiconductor substrate 100 may be a silicon-on-insulator (SOI) substrate or a germanium-on-insulator (GOI) substrate. As used herein, the term “or” is not necessarily an exclusive term, e.g., “A or B” would include A, B, or A and B.

The first separation dielectric pattern STI1 and the second separation dielectric pattern STI2 may be on the semiconductor substrate 100. The first and second separation dielectric patterns STI1 and STI2 may include a dielectric material. In an implementation, the first and second separation dielectric patterns STI1 and STI2 may include silicon oxide, silicon nitride, or a combination thereof. The first and second separation dielectric patterns STI1 and STI2 may be a single layer formed of one material or a composite layer formed of two or more materials. The word line WL may be between the first separation dielectric pattern STI1 and the second separation dielectric pattern STI2.

The first separation dielectric pattern STI1 may be in contact (e.g., direct contact) with the bit line BL. The first separation dielectric pattern STI1 may be between the bit lines BL that are spaced apart from each other in the first direction D1. The first separation dielectric pattern STI1 may be in contact with the vertical dielectric pattern 130.

The second separation dielectric pattern STI2 may be in contact with the data storage element CAP. The second separation dielectric pattern STI2 may be in contact with a capacitor dielectric layer CIL which will be discussed below. The second separation dielectric pattern STI2 may be in contact with a storage electrode SE which will be discussed below.

The stack structure ST may be on the semiconductor substrate 100. The stack structure ST may be a structure stacked in a third direction D3. The stack structure ST may extend (e.g., lengthwise) in the first direction D1. The stack structure ST may include a substrate dielectric layer TIL, a plurality of interlayer dielectric patterns ILD, a plurality of word lines WL that are stacked across the plurality of interlayer dielectric patterns ILD, and a gate dielectric layer Gox between the word lines WL and the interlayer dielectric patterns ILD.

The semiconductor substrate 100 may be provided thereon with the substrate dielectric layer TIL of the stack structure ST. The word lines WL and the interlayer dielectric patterns ILD may be alternately and repeatedly stacked along the third direction D3 perpendicular to the first direction D1 and the second direction D2. The substrate dielectric layer TIL may include a dielectric material. In an implementation, the substrate dielectric layer TIL may include silicon oxide.

The gate dielectric layer Gox may be on the substrate dielectric layer TIL. The gate dielectric layer Gox may be between the substrate dielectric layer TIL and the word line WL. The gate dielectric layer Gox may be between the word line WL and a channel region CH of the semiconductor pattern SP which will be discussed below.

The word line WL may be on the gate dielectric layer Gox. The word line WL may extend in the first direction D1 parallel to the top surface of the semiconductor substrate 100. The word line WL may be between the bit line BL and the data storage element CAP and between the first separation dielectric pattern STI1 and the second separation dielectric pattern STI2. When viewed in a plan view, a pair of word lines WL may be mirror-symmetric about a plate electrode PE which will be discussed below.

The word line WL may have an irregular width. The word line WL may have a shape that is recessed between the first separation dielectric pattern STI1 and the second separation dielectric pattern STI2. A width W1 of the word line WL between the bit line BL and the data storage element CAP may be different from a minimum width W2 of the word line WL between the first separation dielectric pattern STI1 and the second separation dielectric pattern STI2. The width W1 of the word line WL between the bit line BL and the data storage element CAP may be greater than the minimum width W2 of the word line WL between the first separation dielectric pattern STI1 and the second separation dielectric pattern STI2. A width W1 of the word line WL that overlaps the semiconductor pattern SP may be greater than the minimum width W2 of the word line WL between the first separation dielectric pattern STI1 and the second separation dielectric pattern STI2.

The data storage element CAP may be on the semiconductor substrate 100. The data storage element CAP may include a storage electrode SE, a capacitor dielectric layer CIL, and a plate electrode PE.

The storage electrodes SE may be at a level (e.g., distance from the semiconductor substrate 100 in the third direction D3) that is substantially the same as that of the semiconductor patterns SP which will be discussed below. The storage electrodes SE may be stacked in the third direction D3. The storage electrodes SE may be spaced apart from each other in the first direction D1. The storage electrodes SE may be correspondingly between the interlayer dielectric patterns ILD that are vertically adjacent to each other. The storage electrodes SE may each be shaped like a square bracket that protrudes in the second direction D2. The storage electrodes SE may each have a hollow cylindrical shape. In an implementation, the storage electrodes SE may each have a pillar shape that has a major axis in the second direction D2. The storage electrodes SE may include a metal, a metal nitride, or a metal silicide.

The capacitor dielectric layer CIL may conformally cover surfaces of the storage electrodes SE, and the plate electrode PE may be on the capacitor dielectric layer CIL. The capacitor dielectric layer CIL may include a metal oxide such as hafnium oxide, zirconium oxide, aluminum oxide, lanthanum oxide, tantalum oxide, or titanium oxide, or a perovskite-structured dielectric such as SrTiO₃(STO), (Ba, Sr)TiO₃(BST), BaTiO₃, PZT, or PLZT.

The plate electrode PE may fill a space surrounded by the storage electrode SE on which the capacitor dielectric layer CIL is formed. The plate electrode PE may commonly cover the storage electrodes SE that are spaced apart from each other in the third direction D3. The plate electrode PE may extend in the first direction D1 and the third direction D3.

The bit line BL may be on the semiconductor substrate 100. The bit line BL may extend in the third direction D3 perpendicular to the top surface of the semiconductor substrate 100, and the first separation dielectric patterns STI1 may separate the bit lines BL from each other in the first direction D1. The bit lines BL may be spaced apart from each other in the first direction D1 and the second direction D2. The bit line BL may extend in the third direction D3, while running across the word line WL.

The bit lines BL may be in contact with source/drain regions SD of the semiconductor patterns SP which will be discussed below. The bit lines BL may include doped silicon, a metal, a metal nitride, or a metal silicide. In an implementation, the bit lines BL may include tantalum nitride or tungsten.

The semiconductor pattern SP may be between the bit line BL and the data storage element CAP. The semiconductor patterns SP may be stacked in the third direction D3 and may be spaced apart from each other in the first direction DI and the second direction D2. The semiconductor patterns SP may include one or both of silicon and germanium. In an implementation, the semiconductor patterns SP may include monocrystalline silicon.

Each of the semiconductor patterns SP may have a bar shape that has a major axis in the second direction D2. Each of the semiconductor patterns SP may include first and second source/drain regions SD1 and SD2 that are spaced apart from each other, and may also include a channel region CH between the first and second source/drain regions SD1 and SD2. Impurities may be doped in the first and second source/drain regions SD1 and SD2 of each of the semiconductor patterns SP. The first and second source/drain regions SD1 and SD2 of each of the semiconductor patterns SP may include impurities, e.g., boron (B), carbon (C), or fluorine (F).

The semiconductor patterns SP may correspondingly penetrate in the second direction D2 through the word lines WL. Each of the word lines WL may have a structure (e.g., a gate-all-around structure) that completely surrounds the channel region CH. The gate dielectric layer Gox may be between the word line WL and the channel region CH of each of the semiconductor patterns SP. The gate dielectric layer Gox may be in contact with a sidewall of the spacer dielectric pattern SS. The gated dielectric layer Gox may not be in contact with the first source/drain region SD1 of each of the semiconductor patterns SP. The gate dielectric layer Gox may have a sidewall aligned with those of the word lines WL.

Each of the semiconductor patterns SP may have a first sidewall SP_S1 in contact with one of the bit lines BL and a second sidewall SP_S2 in contact with one of the storage electrodes SE. Each of the bit lines BL may be connected to the first source/drain regions SD1 of the semiconductor patterns SP that are stacked in the third direction D3.

The data storage element CAP may be connected to the second source/drain region SD2 of each of the semiconductor patterns SP. The storage electrodes SE of the capacitors CAP may be correspondingly connected to the second source/drain regions SD2 of the semiconductor patterns SP.

A maximum width SD_ W in the first direction D1 of each of the source/drain regions SD1 and SD2 of the semiconductor pattern SP may be less than a maximum width CH_W in the second direction D2 of the channel region CH of the semiconductor pattern SP. When viewed in plan, the maximum width SD_W of each of the source/drain regions SD1 and SD2 of the semiconductor pattern SP may be less than the maximum width CH_W of the channel region CH of the semiconductor pattern SP.

The capping dielectric pattern CP may surround the first source/drain region SD1 of the semiconductor pattern SP on one side of the word line WL, and the spacer dielectric pattern SS may surround the second source/drain region SD2 of the semiconductor pattern SP on another side of the word line WL. The capping dielectric pattern CP may be in direct contact with the sidewall of the word line WL. The bit line BL and the word line WL may be spaced apart from each other across the capping dielectric pattern CP. The spacer dielectric pattern SS may be spaced apart from each of the word lines WL across the gate dielectric layer Gox.

The vertical dielectric pattern 130 may be on the semiconductor substrate 100. The vertical dielectric pattern 130 may extend in the first direction D1 and the third direction D3 that is perpendicular to the top surface of the semiconductor substrate 100. The vertical dielectric pattern 130 may be in contact with the bit line BL. The vertical dielectric pattern 130 may be in contact with the first separation dielectric pattern STI1. The vertical dielectric pattern 130 may be formed of a dielectric material, silicon oxide, or silicon oxynitride.

The etch stop layer OXL may be on the stack structure ST. The etch stop layer OXL may include, e.g., an oxide or a nitride. In an implementation, the etch stop layer OXL may be an oxide or a nitride that further includes, e.g., carbon (C), nitrogen (N), oxygen (O), or boron (B). In an implementation, the etch stop layer OXL may include, e.g., TiN or W. The etch stop layer OXL may have an etch selectivity with respect to the stack structure ST. The etch stop layer OXL may be in contact (e.g., direct contact) with the data storage element CAP, the bit line BL, and the vertical dielectric pattern 130.

The etch stop layer OXL may have an etch selectivity with respect to the stack structure ST, and may help cause a trench and an opening to have a uniform etching degree.

The etch stop layer OXL may have a bottom surface OXL_BS at a same level as that of a top surface BL_TS of the bit line BL (e.g., the surfaces may be coplanar). The level of the bottom surface OXL_BS of the etch stop layer OXL may be the same as that of a top surface CAP_TS of the data storage element CAP. The level of the bottom surface OXL_BS of the etch stop layer OXL may be the same as that of a top surface PE_TS of the plate electrode PE. The level of the bottom surface OXL_BS of the etch stop layer OXL may be the same as that of a top surface of the capacitor dielectric layer CIL.

The etch stop layer OXL may have the bottom surface OXL_BS at a level the same as that of a top surface STI1_TS of the first separation dielectric pattern STI1. The level of the bottom surface OXL_BS of the etch stop layer OXL may be the same as that of a top surface STI2_TS of the second separation dielectric pattern STI2. The level of the bottom surface OXL_BS of the etch stop layer OXL may be the same as that of a top surface of the vertical dielectric pattern 130.

The bottom surface OXL_BS of the etch stop layer OXL may be in contact with the top surface CAP_TS of the data storage element CAP. The bottom surface OXL_BS of the etch stop layer OXL may be in contact with the top surface BL_TS of the bit line BL. The bottom surface OXL_BS of the etch stop layer OXL may be in contact with the top surface PE_TS of the plate electrode PE. The bottom surface OXL_BS of the etch stop layer OXL may be in contact with the top surface of the capacitor dielectric layer CIL.

The bottom surface OXL_BS of the etch stop layer OXL may be in contact with the top surface STI1_TS of the first separation dielectric pattern STI1. The bottom surface OXL_BS of the etch stop layer OXL may be in contact with the top surface STI2_TS of the second separation dielectric pattern STI2. The bottom surface OXL_BS of the etch stop layer OXL may be in contact with the top surface of the vertical dielectric pattern 130.

The bottom surface OXL_BS of the etch stop layer OXL may be coplanar with the top surface BL_TS of the bit line BL, the top surface CAP_TS of the data storage element CAP, the top surface PE_TS of the plate electrode PE, the top surface of the capacitor dielectric layer CIL, the top surface STI1_TS of the first separation dielectric pattern STI1, the top surface STI2_TS of the second separation dielectric pattern STI2, and the top surface of the vertical dielectric pattern 130.

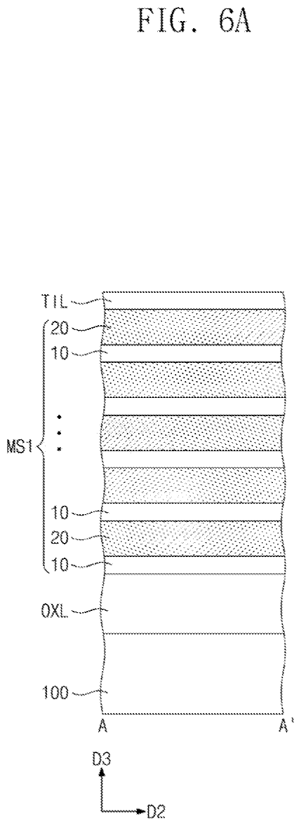

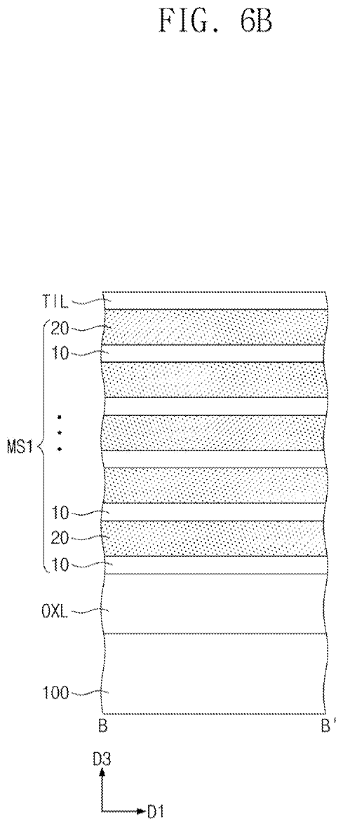

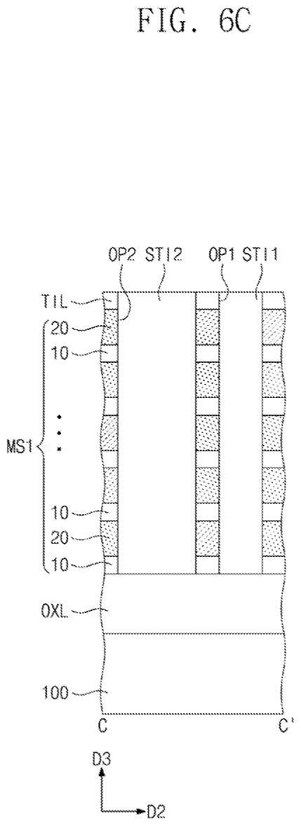

FIGS. 5, 7, 9, 11, 13, 15, 17, and 19 illustrate plan views showing stages in a method of fabricating a semiconductor memory device according to some embodiments. FIGS. 6A to 20A illustrate cross-sectional views taken along line A-A′ of FIGS. 5 to 19, showing stages in a method of fabricating a semiconductor memory device according to some embodiments. FIGS. 6B to 20B illustrate cross-sectional views taken along line B-B′ of FIGS. 5 to 19, showing stages in a method of fabricating a semiconductor memory device according to some embodiments. FIGS. 6C to 20C illustrate cross-sectional views taken along line C-C′ of FIGS. 5 to 19, showing stages in a method of fabricating a semiconductor memory device according to some embodiments.

Referring to FIGS. 5, 6A, 6B, and 6C, an etch stop layer OXL and a first mold structure MS1 may be formed on a semiconductor substrate 100. The first mold structure MS1 may include first sacrificial layers 10 and semiconductor layers 20 that are alternately and repeatedly stacked on the etch stop layer OXL.

In an implementation, the first mold structure MS1 may be formed by alternately stacking the first sacrificial layers 10 and the semiconductor layers 20 on a stress released buffer (SRB) layer, overturning and attaching the first sacrificial layers 10 and the semiconductor layers 20 to the etch stop layer OXL, and then removing the SRB layer. In an implementation, the SRB may remain without being removed.

The first sacrificial layers 10 may be formed of a material having an etch selectivity with respect to the semiconductor layers 20. The first sacrificial layers 10 may be formed of, e.g., silicon-germanium, silicon oxide, silicon nitride, or silicon oxynitride. In an implementation, the first sacrificial layers 10 may include a semiconductor material, such as silicon-germanium. When the first mold structure MS1 is formed, each of the first sacrificial layers 10 may have a thickness less than that of each of the semiconductor layers 20.

The semiconductor layers 20 may include, e.g., silicon, germanium, silicon-germanium, or indium gallium zinc oxide (IGZO). In an implementation, the semiconductor layers 20 may include a semiconductor material that is the same as that of the semiconductor substrate 100. In an implementation, the semiconductor layers 20 may be a monocrystalline silicon layer or a polycrystalline silicon layer.

In an implementation, the first sacrificial layers 10 and the semiconductor layers 20 may be formed by performing an epitaxial growth process. The semiconductor layers 20 may be monocrystalline silicon layers, and the first sacrificial layers 10 may be silicon-germanium layers each having a superlattice structure.

A substrate dielectric layer TIL may be formed on the first mold structure MS1, covering an uppermost semiconductor layer 20. The substrate dielectric layer TIL may be formed of a dielectric material having an etch selectivity with respect to the first sacrificial layers 10 and the semiconductor layers 20. In an implementation, the substrate dielectric layer TIL may be a silicon oxide layer.

The substrate dielectric layer TIL and the first mold structure MS1 may be patterned to form first and second openings OP1 and OP2 that expose the etch stop layer OXL.

The formation of the first and second openings OP1 and OP2 may include forming on the first mold structure MS1 a mask pattern having apertures that correspond to the first and second openings OP1 and OP2, and using the mask pattern as an etching mask to anisotropically etch the first mold structure MS1.

The first and second openings OP1 and OP2 may expose a top surface of the stop layer OXL, and the degree of etching of the etch stop layer OXL may be different from that of the first mold structure MS1, with the result that an over-etching may be prevented.

The first openings OP1 may be formed spaced apart from each other along a first direction D1. The second openings OP2 may be formed spaced apart from each other along the first direction D1, and spaced apart in a second direction D2 from the first openings OP1. A pair of second openings OP2 may be formed between a pair of first openings OP1.

The first and second openings OP1 and OP2 may be filled with first and second separation dielectric patterns STI1 and STI2, respectively.

The first and second separation dielectric patterns STI1 and STI2 may be in contact with the etch stop layer OXL. The first and second separation dielectric patterns STI1 and STI2 may include one of dielectric materials, such as silicon oxide and silicon oxynitride, formed by using spin-on-glass (SOG) technology. The first and second separation dielectric patterns STI1 and STI2 may be formed by depositing a separation dielectric layer to fill the first and second openings OP1 and OP2, and then planarizing the separation dielectric layer to expose a top surface of the substrate dielectric layer TIL.

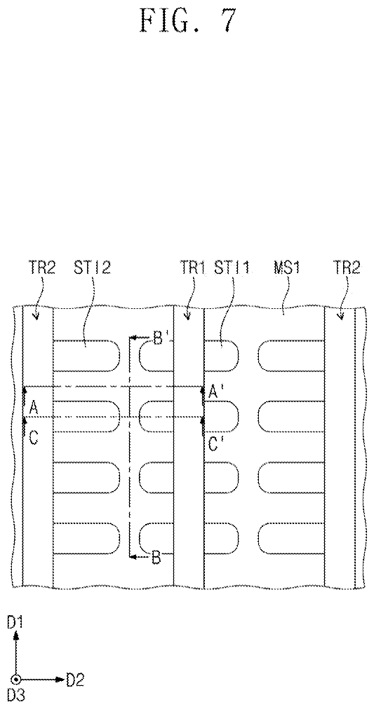

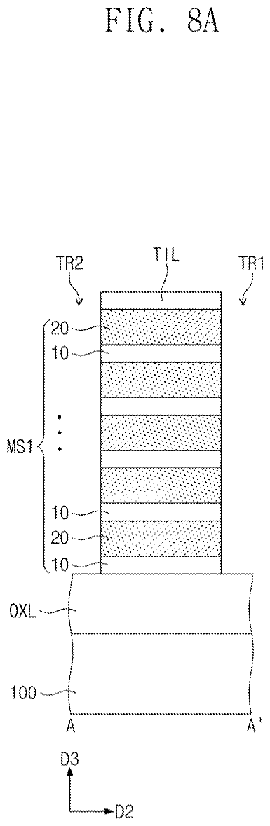

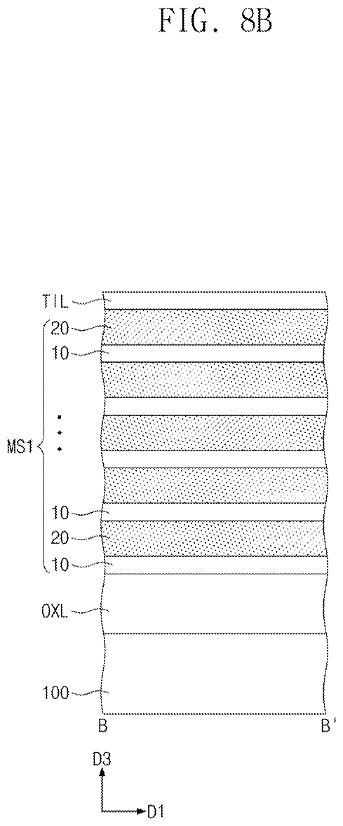

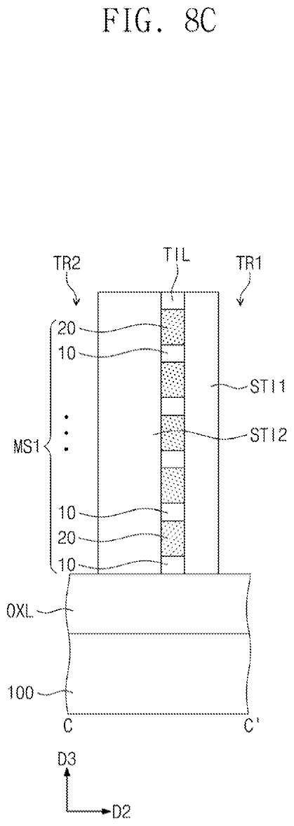

Referring to FIGS. 7, 8A, 8B, and 8C, first and second trenches TR1 and TR2 may be formed to penetrate the first mold structure MS1 to expose sidewalls of the first sacrificial layers 10 and sidewalls of the semiconductor layers 20.

The formation of the first and second trenches TR1 and TR2 may include forming on the first mold structure MS1 a mask pattern having apertures that correspond to the first and second trenches TR1 and TR2, and using the mask pattern to anisotropically etch the first mold structure MS1. The first and second trenches TR1 and TR2 may expose the top surface of the etch stop layer OXL. The degree of etching of the etch stop layer OXL may be different from that of the first mold structure MS1, and an over-etching may be prevented.

The first and second trenches TR1 and TR2 may extend in parallel along the first direction D1. The first and second trenches TR1 and TR2 may expose the sidewalls of the first sacrificial layers 10 and the sidewalls of the semiconductor layers 20. In an implementation, the first trenches TR1 may extend along the first direction D1 to expose sidewalls of the first separation dielectric patterns STI1.

The first trenches TR1 may be formed between a pair of second trenches TR2. The second trenches TR2 may extend along the first direction D1 to expose sidewalls of the second separation dielectric pattern STI2.

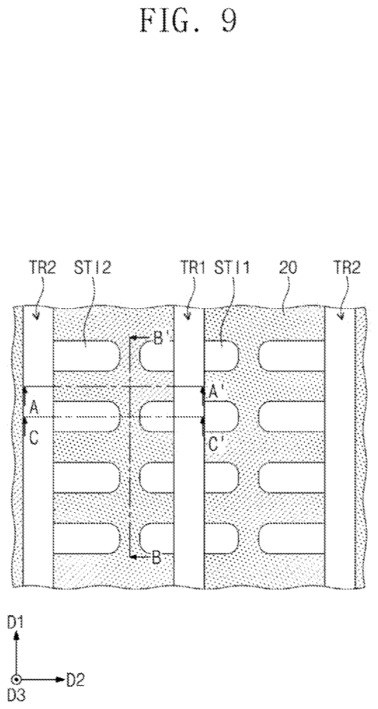

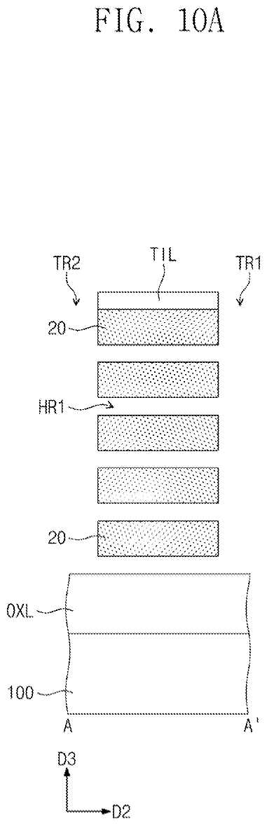

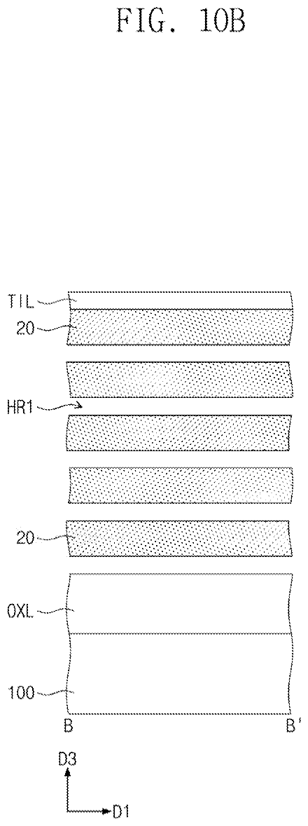

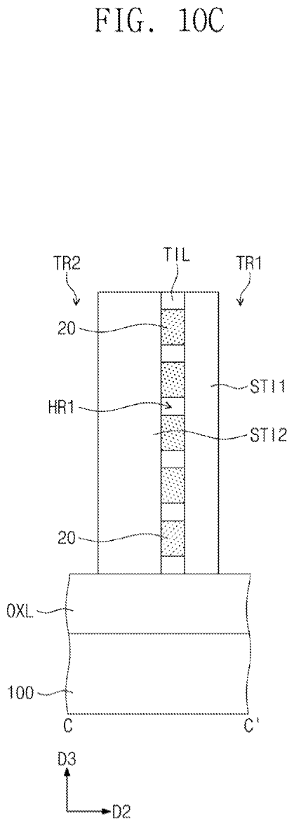

Referring to FIGS. 9, 10A, 10B, and 10C, the first sacrificial layers 10 exposed to the first and second trenches TR1 and TR2 may be removed to form first horizontal regions HR1 between the semiconductor layers 20 that are vertically adjacent to each other.

The formation of the first horizontal regions HR1 may include performing an etching process on the semiconductor substrate 100, the etch stop layer OXL, the semiconductor layers 20, and the first and second separation dielectric patterns STI1 and STI2 to anisotropically etch the first sacrificial layers 10. When the first sacrificial layers 10 are removed, the semiconductor layers 20 may be spaced apart from each other in a third direction D3 without being collapsed by the first and second separation dielectric patterns STI1 and STI2.

A thickness (e.g., height) in the third direction D3 of each of the first horizontal regions HR1, or a distance in the third direction D3 of each of neighboring semiconductor layers 20, may be substantially the same as a thickness of each of the first sacrificial layers 10.

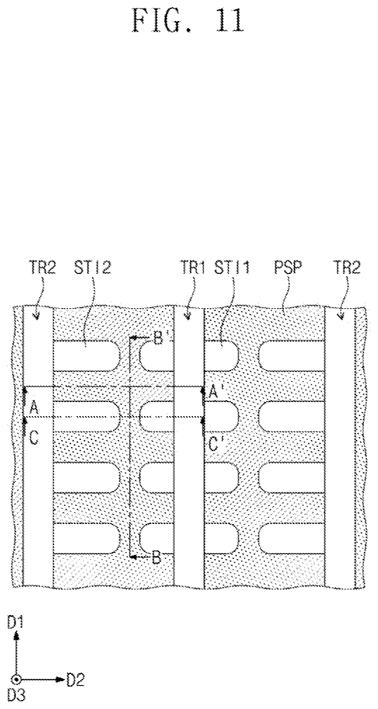

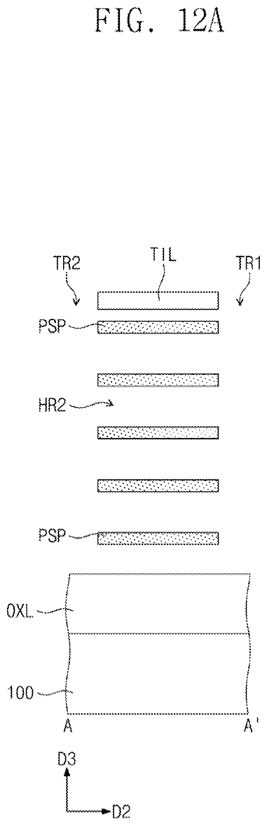

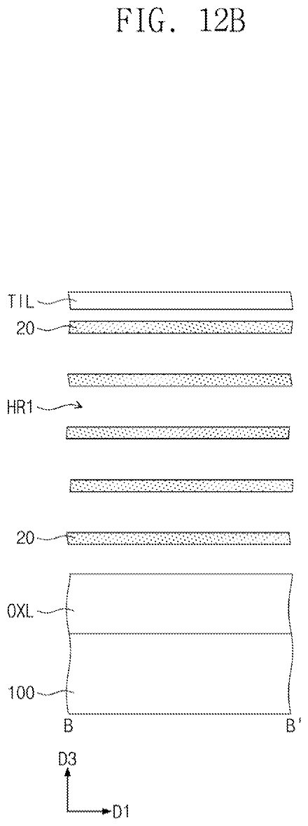

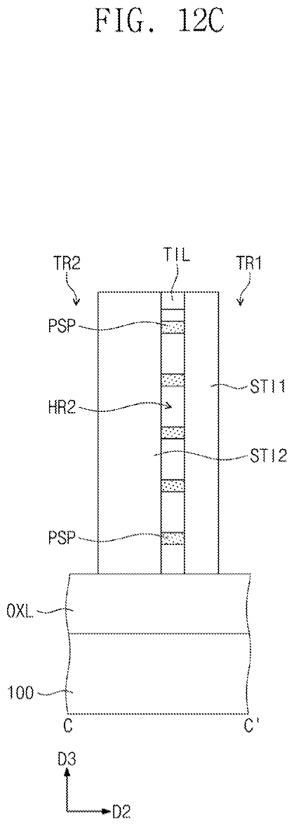

Referring to FIGS. 11, 12A, 12B, and 12C, an enlargement process may be performed to increase a vertical thickness of each of the first horizontal regions HR1. In an implementation, the enlargement process may include etching exposed top and bottom surfaces of the semiconductor layers 20 exposed to the first horizontal regions HR1. The enlargement process may include performing an isotropic etching process having an etch selectivity with respect to the substrate dielectric layer TIL and the first and second separation dielectric patterns STI1 and STI2. The enlargement process may cause the semiconductor layers 20 to have their reduced thicknesses. In an implementation, semiconductor patterns SP may be formed, and second horizontal regions HR2 may be correspondingly formed between the semiconductor patterns SP that are adjacent to each other in the third direction D3.

In an implementation, an oxidation process may be performed on the semiconductor patterns SP to thereby form sacrificial oxide layers on surfaces of the semiconductor patterns SP. Afterwards, the sacrificial oxide layers may be removed to re-expose the surfaces of the semiconductor patterns SP. After the removal of the sacrificial oxide layers, there may be an increase in distance between the semiconductor patterns SP that are adjacent to each other in the third direction D3. In an implementation, the second horizontal regions HR2 may additionally expand vertically.

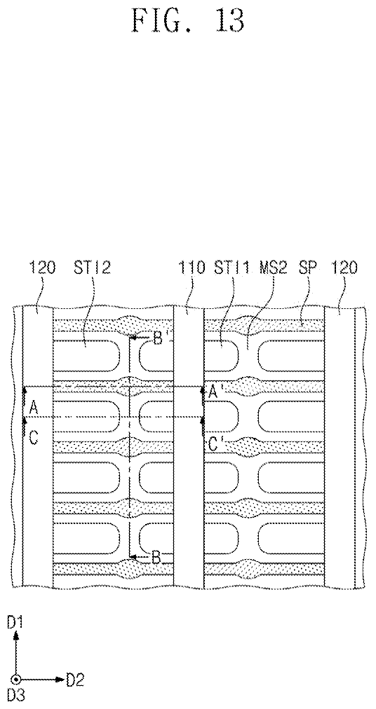

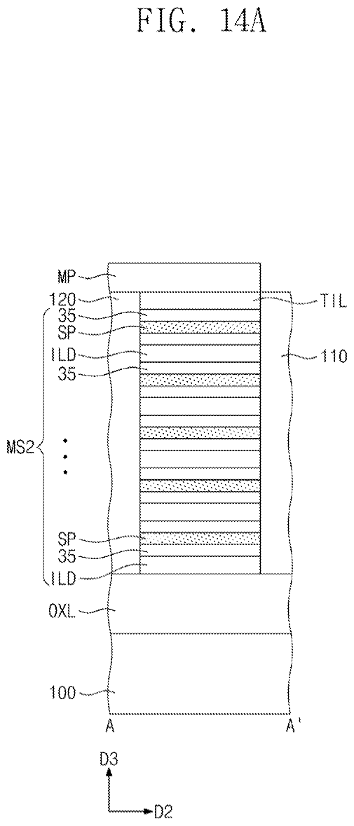

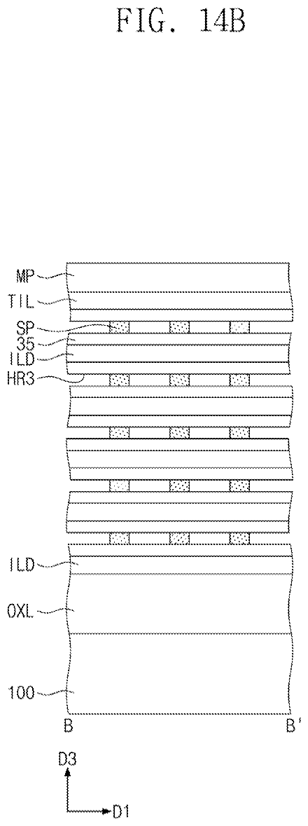

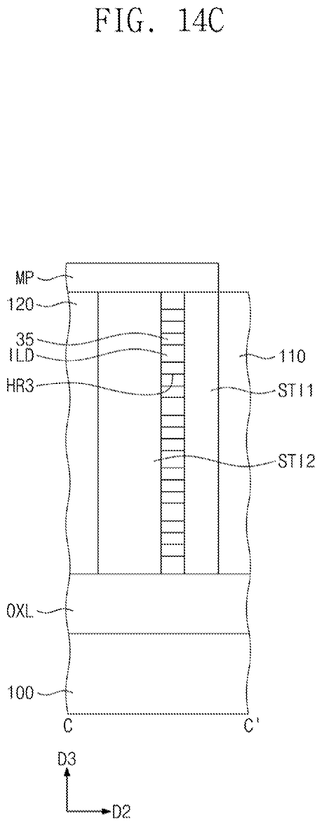

Referring to FIGS. 13, 14A, 14B, and 14C, a second sacrificial pattern 35 and an interlayer dielectric pattern ILD may be sequentially deposited on the surfaces of the semiconductor patterns SP to form a second mold structure MS2.

The second sacrificial pattern 35 may be formed by depositing a material having an etch selectivity with respect to the semiconductor substrate 100 and the semiconductor patterns SP. The second sacrificial pattern 35 may be formed of, e.g., silicon oxide, silicon nitride, or silicon oxynitride. The second sacrificial pattern 35 may be formed by atomic layer deposition or chemical vapor deposition.

The interlayer dielectric pattern ILD may be formed on the second sacrificial pattern 35 so as to fill the second horizontal regions HR2 in which the second sacrificial pattern 35 is formed. The interlayer dielectric pattern ILD may be formed of a dielectric material having an etch selectivity with respect to the second sacrificial pattern 35 and the semiconductor substrate 100. In an implementation, the interlayer dielectric pattern ILD may be formed of silicon oxide.

The second mold structure MS2 formed as discussed above may include the interlayer dielectric patterns ILD, the second sacrificial patterns 35, and the semiconductor patterns SP. In an implementation, the second mold structure MS2 may include a plurality of stack structures, and each of the stack structures may include the semiconductor pattern SP, the second sacrificial pattern 35, the interlayer dielectric pattern ILD, and the second sacrificial pattern 35 that are sequentially stacked.

After the formation of the second mold structure MS2, first and second buried dielectric patterns 110 and 120 may be formed to fill the first and second trenches TR1 and TR2. The formation of the first and second buried dielectric patterns 110 and 120 may include forming a buried dielectric layer to fill the first and second trenches TR1 and TR2, and planarizing the buried dielectric layer to the top surface of the upper dielectric layer TIL. The planarization of the buried dielectric layer may be performed by planarization technology such as a chemical mechanical polishing process or an etch-back process.

The first and second buried dielectric patterns 110 and 120 may be formed of a dielectric material having an etch selectivity with respect to the first and second separation dielectric patterns STI1 and STI2. In an implementation, the first and second buried dielectric patterns 110 and 120 may be formed of silicon oxide, silicon nitride, or silicon oxynitride. The first and second buried dielectric patterns 110 and 120 may each be formed of a single layer or a multiple layer.

After the formation of the first and second buried dielectric patterns 110 and 120, the first and second separation dielectric patterns STI1 and STI2 may be removed to form first and second openings. The first and second openings may expose sidewalls of the semiconductor patterns SP, sidewalls of the second sacrificial patterns 35, and sidewalls of the interlayer dielectric patterns ILD.

An etching process may be performed on portions of the semiconductor patterns SP exposed to the first and second openings. Therefore, the semiconductor patterns SP may be separated from each other in the first direction D1.

The semiconductor patterns SP may be formed as discussed above, and third horizontal regions HR3 may be formed to expose the sidewalls of the semiconductor patterns SP between the second sacrificial patterns 35. The third horizontal regions HR3 may correspond to areas where the semiconductor patterns SP are etched.

The first and second openings may be re-filled with a dielectric material to re-form the first and second separation dielectric patterns STI1 and STI2.

During the formation of the first and second separation dielectric patterns STI1 and STI2, the third horizontal regions HR3 may be filled with a dielectric material or may remain as empty spaces.

After the re-formation of the first and second separation dielectric patterns STI1 and STI2, a mask pattern MP may be formed on the substrate dielectric layer TIL to expose the first buried dielectric patterns 110.

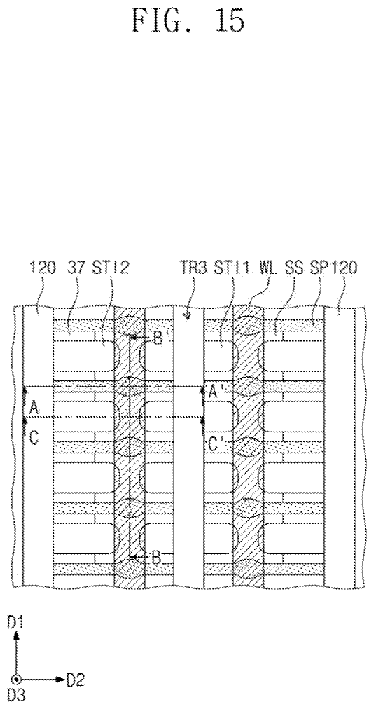

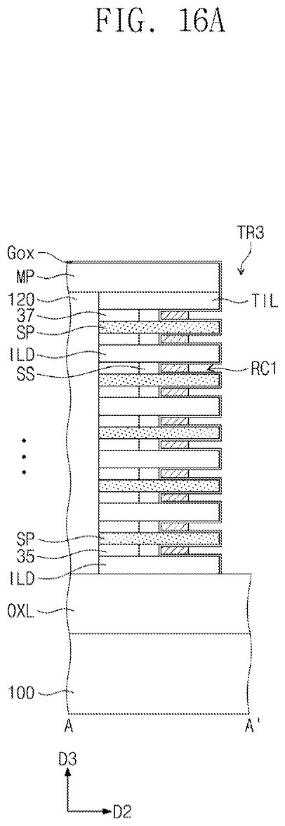

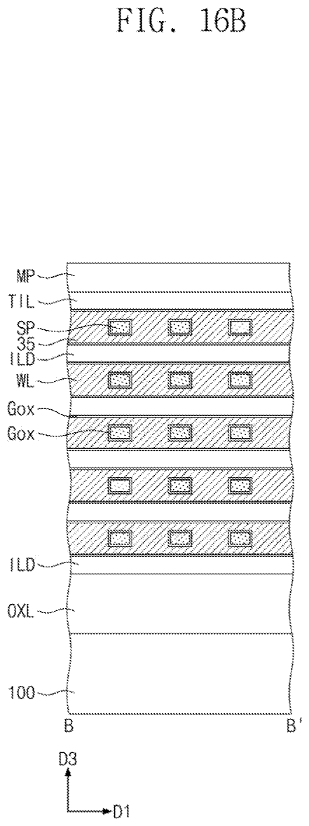

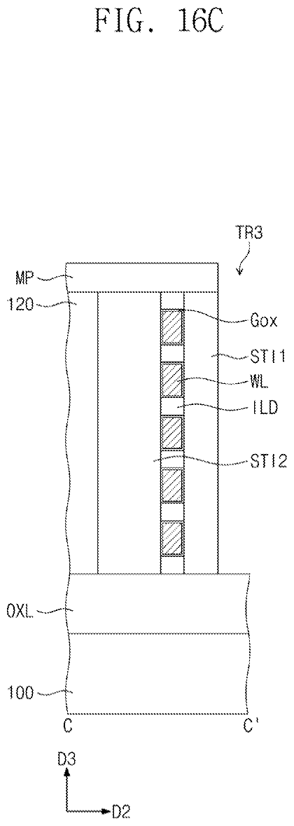

Referring to FIGS. 15, 16A, 16B, and 16C, the mask pattern MP may be used as an etching mask to etch the first buried dielectric patterns 110 to form a third trench TR3 that exposes the etch stop layer OXL. The third trench TR3 may expose the sidewalls of the semiconductor patterns SP, the sidewalls of the second sacrificial patterns 35, and the sidewalls of the interlayer dielectric patterns ILD.

Thereafter, portions of the second sacrificial patterns 35 exposed to or at the third trench TR3 may be removed, and then ad dielectric layer may be deposited in the removed portions to form a spacer dielectric pattern SS. Third sacrificial patterns 37 may be formed from remaining portions of the second sacrificial patterns 35 after the partial removal of the second sacrificial patterns 35. The second separation dielectric patterns STI2 may separate the third sacrificial patterns 37 from each other in the first direction D1.

After the formation of the spacer dielectric pattern SS, a gate dielectric layer Gox may be formed to conformally cover an inner wall of the third trench TR3, a sidewall of the spacer dielectric pattern SS, and the exposed semiconductor pattern SP and the interlayer dielectric pattern ILD.

After the formation of the gate dielectric layer Gox, a word line WL may be formed on the gate dielectric layer Gox. The gate dielectric layer Gox may separate the word line WL from the interlayer dielectric pattern ILD and the semiconductor pattern SP. The formation of the word line WL may include, e.g., depositing a preliminary word line through the third trench TR3, etching the preliminary word line, and then forming a recess region RC1 that is recessed in the second direction D2.

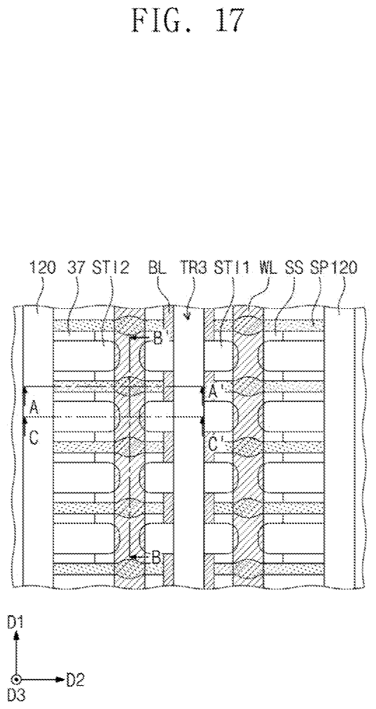

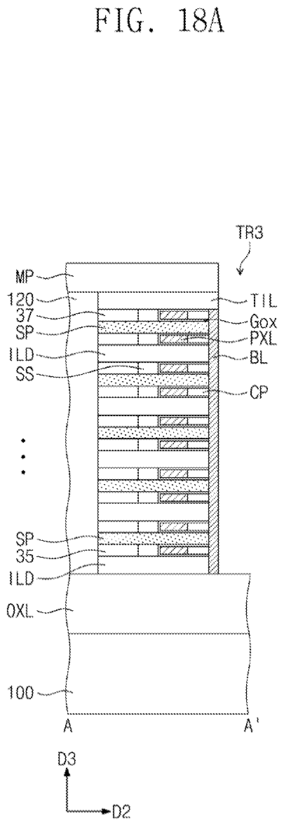

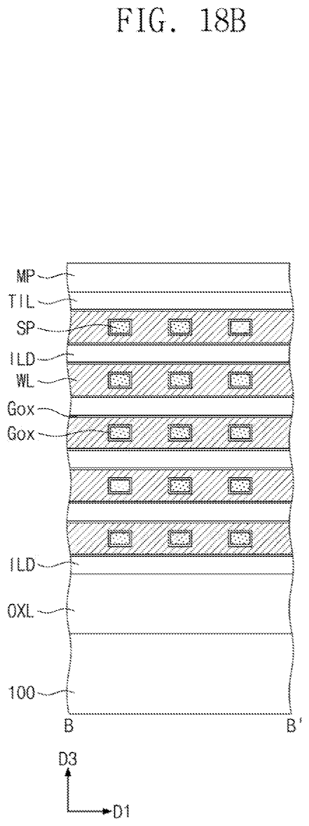

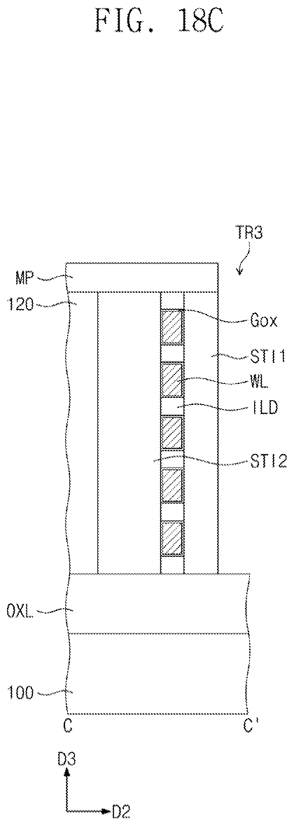

Referring to FIGS. 17, 18A, 18B, and 18C, capping dielectric patterns CP may be formed to fill spaces where the word lines WL are recessed. The formation of the capping dielectric patterns CP may include forming a capping dielectric layer to fill the third trench TR3 and removing a portion of the capping dielectric layer. Before or after the formation of the capping dielectric patterns CP, impurities may be doped into portions of the semiconductor patterns SP exposed to the third trenches TR3. Therefore, first source/drain regions SD1 may be formed in the semiconductor patterns SP. The first source/drain regions SD1 may be formed by performing a gas phase doping (GPD) process or a plasma doping (PLAD) process through the third trenches TR3.

A bit line BL may be formed to cover an inner wall of the capping dielectric pattern CP in the third trench TR3. The formation of the bit line BL may include forming a conductive layer to fill the third trench TR3 and performing a patterning process on the conductive layer.

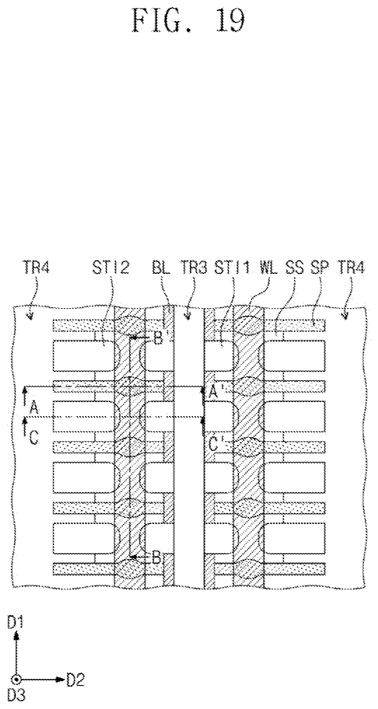

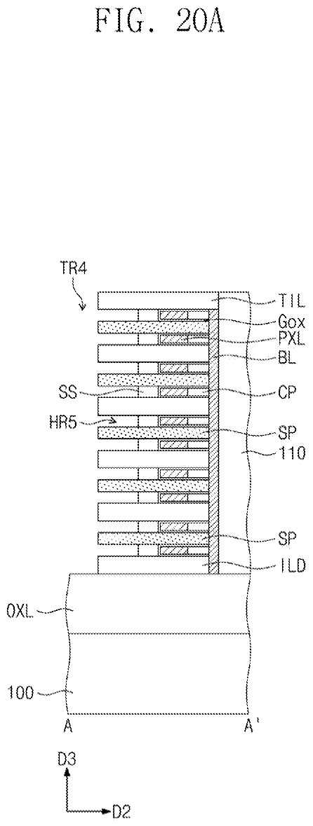

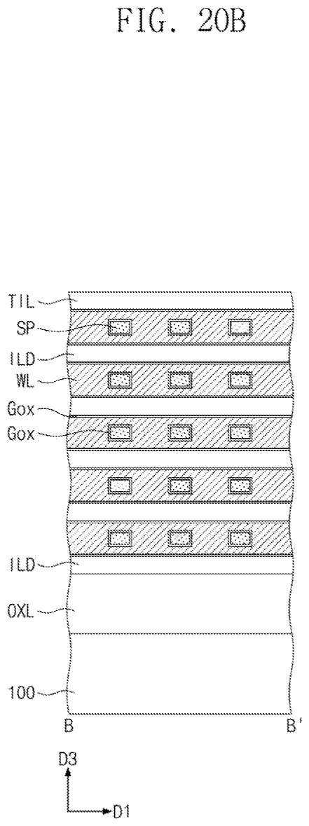

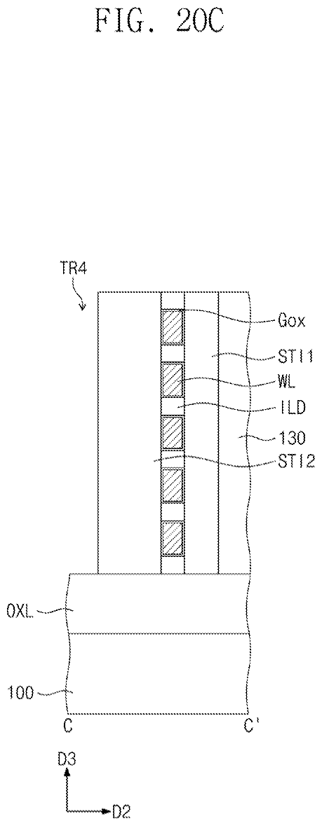

Referring to FIGS. 19, 20A, 20B, and 20C, after the formation of the bit lines BL, a vertical dielectric pattern 130 may be formed in the third trench TR3. The vertical dielectric pattern 130 may extend along the first direction D1 on the etch stop layer OXL. The vertical dielectric pattern 130 may sidewalls of the bit lines BL and sidewalls of the first separation dielectric patterns STI1. The vertical dielectric pattern 130 may be formed of one of dielectric materials, such as silicon oxide and silicon oxynitride, formed by using spin-on-glass (SOG) technology.

The second buried dielectric pattern 120 and the mask pattern MP may be removed to form a fourth trench TR4.

The third sacrificial patterns 37 exposed to the fourth trench TR4 may be removed to form fifth horizontal regions HR5 that expose the spacer dielectric patterns SS.

The formation of the fifth horizontal regions HR5 may include isotropically etching the third sacrificial patterns 37 by performing an etching process that has an etch selectivity with respect to the semiconductor substrate 100, the semiconductor patterns SP, and the interlayer dielectric patterns ILD. When the third sacrificial patterns 37 are isotropically etched, the spacer dielectric patterns SS may be used as an etch stop layer.

The fifth horizontal regions HR5 may be correspondingly formed vertically between the interlayer dielectric patterns ILD and the semiconductor patterns SP and horizontally between the second separation dielectric patterns STI2.

Portions of the semiconductor patterns SP exposed to or at the fifth horizontal regions HR5 may be etched to reduce lengths in the second direction D2 of the semiconductor patterns SP. In an implementation, after the formation of the fifth horizontal regions HR5, portions of the semiconductor patterns SP may be isotropically etched.

Referring back to FIGS. 3, 4A, 4B, and 4C, storage electrodes SE may be locally formed in the fifth horizontal regions HR5. The orientation of FIGS. 3, 4A, 4B, and 4C is inverted relative to that of FIGS. 6A to 20C.

The formation of the storage electrodes SE may include forming a conductive layer to conformally cover inner walls of the fifth horizontal regions HR5 and an inner wall of the fourth trench TR4, removing portions of the conductive layer deposited on the inner wall of the fourth trench TR4 to locally leave conductive patterns in the fifth horizontal regions HR5.

The storage electrodes SE may be spaced apart from each other in the first direction D1, the second direction D2, and the third direction D3. The storage electrodes SE may be in contact with the semiconductor patterns SP exposed to the fifth horizontal regions HR5. The storage electrodes SE may define empty spaces in the fifth horizontal regions HR5. In an implementation, each of the storage electrodes SE may have a major axis in the second direction D2 and may have a hollow cylindrical shape. In an implementation, each of the storage electrodes SE may have a pillar shape that has a major axis in the second direction D2. The storage electrode SE may include a metal, a metal nitride, or a metal silicide.

Prior to the formation of the storage electrodes SE, portions of the semiconductor patterns SP may be doped with impurities to form second source/drain regions SD2, and the storage electrodes SE may be in contact with the second source/drain regions SD2.

A capacitor dielectric layer CIL may be formed to conformally cover the fifth horizontal regions HR5 in which the storage electrodes SE are formed, and a plate electrode PE may be formed to fill the second trenches TR2 and the fifth horizontal regions HR5 in which are formed the storage electrodes SE and the capacitor dielectric layer CIL.

In the fabrication process, when the first, second, and third trenches TR1, TR2, and TR3 and openings are formed, the etch stop layer OXL may allow the first, second, and third trenches TR1, TR2, and TR3 and the openings to have the same etching depth in a vertical direction.

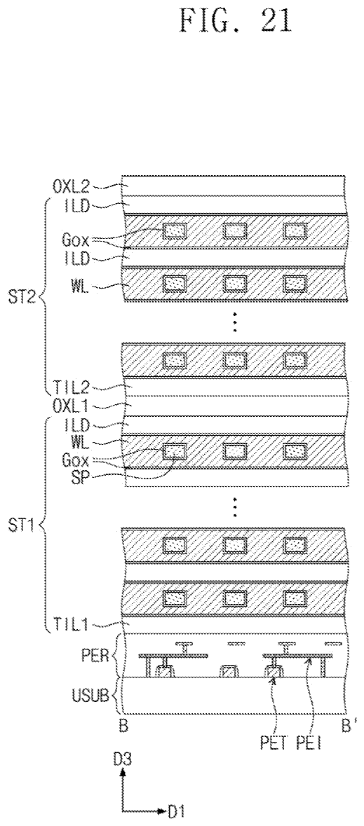

FIG. 21 illustrates a cross-sectional view showing a semiconductor memory device according to some embodiments.

Referring to FIG. 21, a semiconductor device according to an embodiment may include a lower substrate USUB, a peripheral layer PER on the lower substrate USUB, a first stack structure ST1 on the peripheral layer PER, a first etch stop layer OXL1 on the first stack structure ST1, a second stack structure ST2 on the first etch stop layer OXL1, and a second etch stop layer OXL2 on the second stack structure ST2.

The lower substrate USUB may be a silicon substrate, a germanium substrate, or a silicon-germanium substrate. The peripheral layer PER may be between the lower substrate USUB and the first stack structure ST1. The peripheral layer PER may include a plurality of peripheral transistors PET and a plurality of peripheral lines PEI on the lower substrate USUB. The peripheral lines PEI may be on the peripheral transistors PET and may be connected through contacts to the peripheral transistors PET.

The first stack structure ST1 may be on the peripheral layer PER. The first stack structure ST1 may be a structure stacked in the third direction D3. The first stack structure ST1 may extend in the first direction D1. The first stack structure ST1 may include a first substrate dielectric layer TIL, a plurality of interlayer dielectric patterns ILD, a plurality of word lines WL that are stacked across the interlayer dielectric patterns ILD, and a gate dielectric layer Gox interposed between the word lines WL and the interlayer dielectric patterns ILD.

The first etch stop layer OXL1 may be on the first stack structure ST1. The first etch stop layer OXLI may include an oxide or a nitride. In an implementation, the first etch stop layer OXLI may be an oxide or a nitride that further includes carbon (C), nitrogen (N), oxygen (O), or boron (B). In an implementation, the first etch stop layer OXL1 may include, e.g., TiN or W.

The second stack structure ST2 may be on the first etch stop layer OXL1. The second stack structure ST2 may be analogous to the first stack structure ST1. The first stack structure ST1 and the second stack structure ST2 may be electrically connected to each other through a through via, a through post, or a wiring structure in the first etch stop layer OXL1.

The second etch stop layer OXL2 may be on the second stack structure ST2. In an implementation, the second etch stop layer OXL2 may include a material different from that of the first etch stop layer OXL1. In an implementation, when the first etch stop layer OXL1 includes an oxide such as SiO₂, the second etch stop layer OXL2 may include a nitride such as SiN.

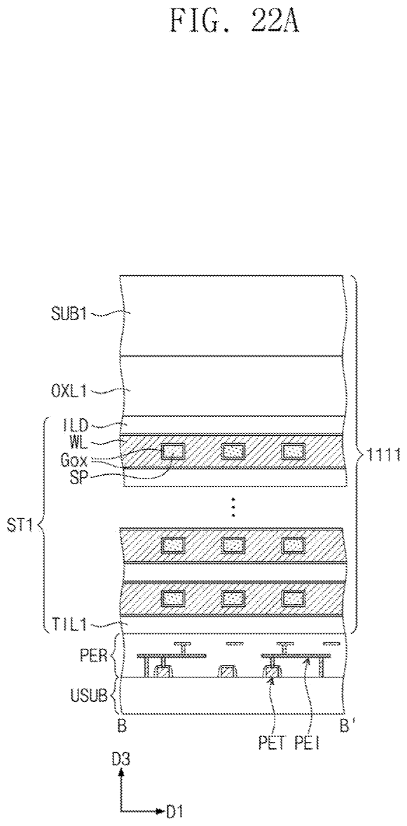

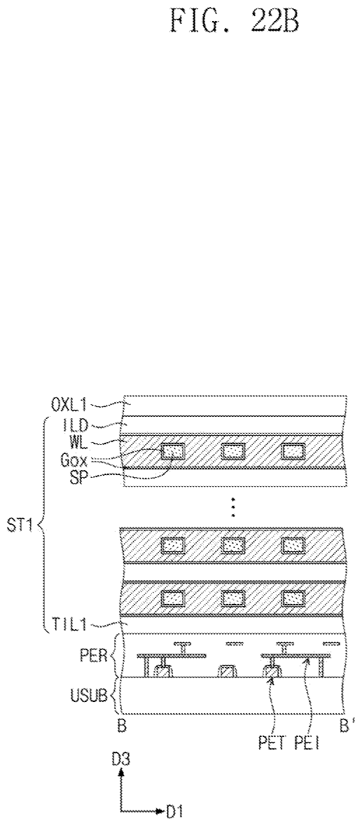

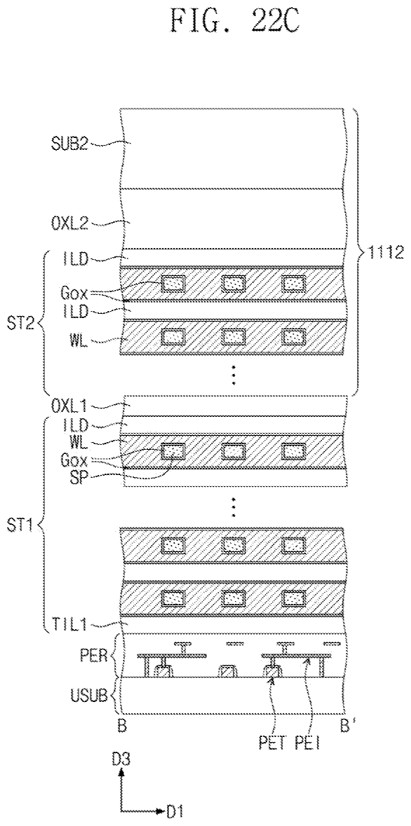

FIGS. 22A, 22B, and 22C illustrate cross-sectional views of stages in a method of fabricating a semiconductor memory device according to some embodiments.

Referring to FIG. 22A, in a method similar to that discussed with reference to FIGS. 5 to 20A, a first semiconductor device 1111 may be fabricated which includes a first substrate SUB1, a first etch stop layer OXL1 on the first substrate SUB1, and a first stack structure ST1 on the first etch stop layer OXL1.

The first semiconductor device 1111 may be flipped and attached to the peripheral layer PER on the lower substrate USUB. In an implementation, the peripheral layer PER may be in contact with a first substrate dielectric layer TIL1 of the first stack structure ST1.

Referring to FIG. 22B, the first substrate SUB1 and the first etch stop layer OXL1 may be partially etched. In an implementation, the first etch stop layer OXL1 may be partially removed after the first substrate SUB1 may be completely removed, the first etch stop layer OXL1 may cause the first stack structure ST1 to have a top surface that is not exposed, and thus the first stack structure ST1 may be free of damage.

Referring to FIG. 22C, similarly to the first semiconductor device 1111, a second semiconductor device 1112 may be attached to the first etch stop layer OXL1, which second semiconductor device 1112 may include a second substrate SUB2, a second etch stop layer OXL2 on the second substrate SUB2, and a second stack structure ST2 on the second etch stop layer OXL2.

The second substrate SUB2 and the second etch stop layer OXL2 may be partially etched. In an implementation, the second etch stop layer OXL2 may be partially removed after the second substrate SUB2 is completely removed, the second etch stop layer OXL2 may cause the second stack structure ST2 to have a top surface that is not exposed, and thus the second stack structure ST2 may be free of damage.

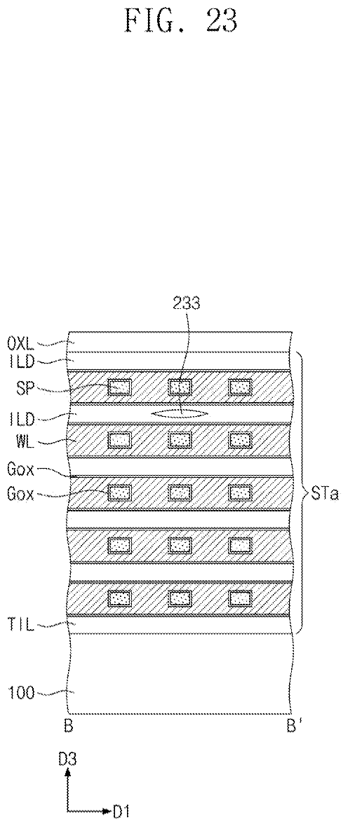

FIG. 23 illustrates a cross-sectional view showing a semiconductor memory device according to some embodiments.

Referring to FIG. 23, a semiconductor memory device according to an embodiment may include a semiconductor substrate 100, a stack structure STa on the semiconductor substrate 100, and an etch stop layer OXL on the stack structure STa.

The stack structure STa may be analogous to the stack structure ST of FIGS. 3, 4A, and 4B, and may further include an air gap 233 in the interlayer dielectric pattern ILD. The air gap 233 may help induce an increase in dielectric properties. In an implementation, the air gap 233 may be replaced with a dielectric material different from that of the interlayer dielectric pattern ILD.

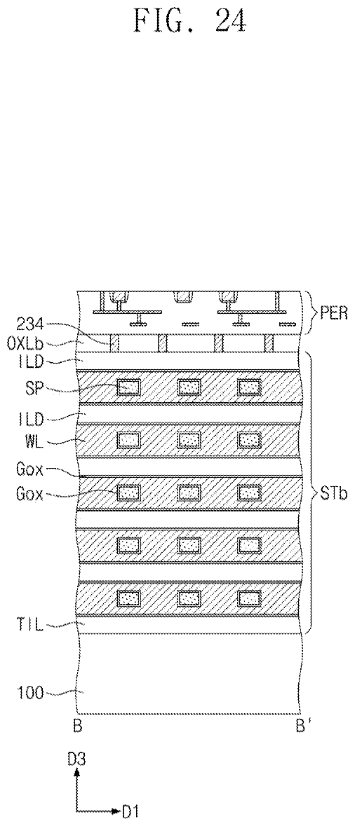

FIG. 24 illustrates a cross-sectional view showing a semiconductor memory device according to some embodiments.

Referring to FIG. 24, a semiconductor memory device according to an embodiment may include a semiconductor substrate 100, a stack structure STb on the semiconductor substrate 100, an etch stop layer OXLb on the stack structure STb, and a peripheral layer PER on the etch stop layer OXLb.

The etch stop layer OXLb may be analogous to the etch stop layer OXL of FIGS. 3, 4A, and 4B, and may include a connection post 234 therein. The connection post 234 may include a conductive material. In an implementation, the connection post 234 may include copper. The stack structure STb, the etch stop layer OXLb, and the peripheral layer PER may be electrically connected to each other through the connection post 234.

According to some embodiments, during an etching process in fabrication process for a semiconductor memory device, an etch stop layer on a semiconductor substrate may facilitate etching of stacked objects to a uniform depth, and a distribution of trenches may be controlled in a subsequent patterning process.

One or more embodiments may provide a semiconductor memory device having improved electrical properties.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor memory device, comprising:
a semiconductor substrate;
a stack structure that includes word lines and interlayer dielectric patterns that are alternately stacked on the semiconductor substrate;
an etch stop layer on the stack structure;
semiconductor patterns that penetrate the word lines;
a bit line in contact with the semiconductor patterns;
capping dielectric patterns between the bit line and the word lines, the capping dielectric patterns covering sidewalls of the word lines; and
a data storage element on the semiconductor substrate,
wherein a level of a bottom surface of the etch stop layer is the same as a level of a top surface of the data storage element.

2. The device as claimed in claim 1, wherein a level of a top surface of the bit line is the same as the level of the bottom surface of the etch stop layer.

3. The device as claimed in claim 1, wherein the bottom surface of the etch stop layer is in contact with the data storage element.

4. The device as claimed in claim 1, wherein the bottom surface of the etch stop layer is in contact with the bit line.

5. The device as claimed in claim 1, wherein:
the semiconductor patterns include:
first lateral surfaces in contact with the bit line; and
second lateral surfaces in contact with the data storage elements,
the data storage element includes:
storage electrodes in contact with the second lateral surfaces of the semiconductor patterns and parallel to a top surface of the semiconductor substrate;
a capacitor dielectric layer that conformally covers the storage electrodes; and
a plate electrode on the capacitor dielectric layer, and
the bottom surface of the etch stop layer is in contact with a top surface of the plate electrode.

6. The device as claimed in claim 1, wherein:
the semiconductor patterns include:
first lateral surfaces in contact with the bit line; and
second lateral surfaces in contact with the data storage elements, the data storage element includes:
storage electrodes in contact with the second lateral surfaces of the semiconductor patterns and parallel to a top surface of the semiconductor substrate;
a capacitor dielectric layer that conformally covers the storage electrodes; and
a plate electrode on the capacitor dielectric layer, and
the bottom surface of the etch stop layer is in contact with a top surface of the capacitor dielectric layer.

7. The device as claimed in claim 1, wherein the etch stop layer includes an oxide.

8. The device as claimed in claim 1, further comprising:
a first separation dielectric pattern between the bit lines; and
a second separation dielectric pattern between the data storage elements,
wherein a level of a top surface of the first separation dielectric pattern is the same as the level of the bottom surface of the etch stop layer.

9. The device as claimed in claim 1, further comprising a vertical dielectric pattern in contact with the bit line,
wherein the bottom surface of the etch stop layer is in contact with a top surface of the vertical dielectric pattern.

10. The device as claimed in claim 1, wherein:
the interlayer dielectric patterns include an air gap, and
the etch stop layer includes TiN or W.

11. A semiconductor memory device, comprising:
a semiconductor substrate;
a stack structure that includes word lines and interlayer dielectric patterns that are alternately stacked on the semiconductor substrate;
an etch stop layer on the stack structure;
semiconductor patterns that penetrate the word lines;
a bit line in contact with the semiconductor patterns;
capping dielectric patterns between the bit line and the word lines, the capping dielectric patterns covering sidewalls of the word lines; and
a data storage element on the semiconductor substrate,
wherein a level of a bottom surface of the etch stop layer is the same as a level of a top surface of the bit line.

12. The device as claimed in claim 11, wherein the etch stop layer includes SiO₂ or SiN.

13. The device as claimed in claim 12, wherein the etch stop layer further includes C, N, O, or B.

14. The device as claimed in claim 11, further comprising a peripheral layer on the etch stop layer, wherein:
the etch stop layer includes a connection post, and
the stack structure and the peripheral layer are electrically connected through the connection post.

15. The device as claimed in claim 11, wherein:
the data storage element includes:
storage electrodes in contact with lateral surfaces of the semiconductor patterns and parallel to a top surface of the semiconductor substrate;
a capacitor dielectric layer that conformally covers the storage electrodes; and
a plate electrode on the capacitor dielectric layer,
a level of a top surface of the plate electrode is the same as the level of the bottom surface of the etch stop layer.

16. The device as claimed in claim 15, wherein the bottom surface of the etch stop layer is in contact with a top surface of the capacitor dielectric layer.

17. The device as claimed in claim 15, wherein the bottom surface of the etch stop layer is in contact with a top surface of the plate electrode.

18. The device as claimed in claim 11, further comprising a vertical dielectric pattern in contact with the bit line,
wherein a top surface of the vertical dielectric pattern is coplanar with the bottom surface of the etch stop layer.

19. A semiconductor memory device, comprising:
a lower substrate;
a peripheral layer on the lower substrate;
a first stack structure that includes word lines and interlayer dielectric patterns that are alternately stacked on the peripheral layer;
a first etch stop layer on the first stack structure;
a second stack structure that includes word lines and interlayer dielectric patterns that are alternately stacked on the first etch stop layer; and
a second etch stop layer on the second stack structure,
wherein the first stack structure and the second stack structure are electrically connected to each other.

20. The device as claimed in claim 19, wherein the first etch stop layer and the second etch stop layer include different materials from each other.
